(19) United States
(12) Patent Application Publication
(10) Pub. No.: US 2013/0047738 A1
(43) Pub. Date: Feb. 28, 2013

(54) PLATFORM WITH ASPHERICAL MEMBRANE BED, PRESSURE SENSOR WITH SUCH A PLATFORM AND METHOD FOR THEIR MANUFACTURE

(71) Applicants: Anh Tuan Tham, Berlin (DE); Dieter Stolze, Potsdam (DE); Rafael Teipen, Berlin (DE)

(72) Inventors: Anh Tuan Tham, Berlin (DE); Dieter Stolze, Potsdam (DE); Rafael Teipen, Berlin (DE)

(73) Assignee: Endress + Hauser GmbH + Co. KG, Maulburg (DE)

(21) Appl. No.: 13/696,453

(22) PCT Filed: Apr. 14, 2011
(86) PCT No.: PCT/EP2011/055946

§ 371 Date: Nov. 6, 2012

(30) Foreign Application Priority Data
May 7, 2010 (DE) 102010028773.3

(51) Int. Cl. B81C 1/00; C01B 33/02; G01L 9/00

(52) U.S. Cl. 73/723; 264/400; 216/2; 73/715; 428/156

(57) ABSTRACT

A method for the manufacture of a platform having a membrane bed includes providing a platform body, which comprises silicon; and removing silicon material from a surface of the platform body by means of laser ablation. Preferably, this is followed by oxidizing the ablated surface and then etching the oxidized surface. In an example of the invention, a resulting pressure sensor comprises two platforms, each with a membrane bed having a contour for supporting a measuring membrane, wherein the contour essentially corresponds to a bend line of the measuring membrane.

The present invention relates to a platform with an aspherical membrane bed for a pressure sensor, to a pressure sensor with such a platform, especially a pressure difference sensor with one or two such platforms, as well as to a manufacturing process therefor.

Pressure sensors usually comprise a platform, a measuring membrane and a transducer, wherein the measuring membrane is secured to the platform, wherein the measuring membrane is contactable with at least one pressure and has a pressure-dependent, elastic deformation, and wherein the transducer provides a signal dependent on the deformation of the measuring membrane. Especially in the case of pressure difference sensors, the platform furthermore includes a membrane bed, against which the measuring membrane lies in the case of overload, in order to support the measuring membrane against further deflection. In such case, it is advantageous when the membrane bed has a contour, which corresponds to the bend line of the measuring membrane, because an optimal support in the case of a measuring membrane overload is clearly given thereby. A membrane bed with such a contour is described, for example, in U.S. Pat. No. 7,360,431 B2, wherein the distance from the membrane plane D(r) is given by the equation:

D(r)=Dₘₐₓ(1−(r/R)²)²

wherein r is the radial distance of the considered point of the membrane bed from the central axis of the membrane, wherein Dₘₐₓ is the maximum depth of the membrane bed, and wherein R is the radius of the membrane.

Such patent describes, among others things, the manufacture of such a membrane bed by a lithographic method, in the case of which a light sensitive protective layer is deposited on the surface of a silicon substrate or a glass substrate, wherein the protective layer is then illuminated by a gray scale distribution corresponding to the membrane bed contour, in order to represent a concave surface in the protective layer. Then, the silicon or glass substrate with the protective layer prepared in such a way is exposed to an etching method or the like, in order to actually transform the representation into the desired surface structure in the substrate material.

The described manufacturing process is, however, difficult to control, insofar as a uniform preparation of the concave structures by illuminating gray scale masks over an entire wafer with sufficiently small tolerances is difficult. Additionally, with the method, the desired contours can be prepared with an acceptable accuracy with a depth of, at most, about 2 micrometers. Furthermore, the described method is time consuming and expensive.

An object of the present invention is therefore to overcome said disadvantages of the state of the art.

The object is achieved according to the invention by the method according to independent patent claim 1, the platform according to independent patent claim 10, and the pressure sensor according to independent claim 14.

The method of the invention for manufacture of a platform with a membrane bed includes providing a platform body—which comprises, for example, semiconductor material, especially silicon—and removing material from a surface of the platform body by means of a laser ablation method.

In a further development of the invention, the method furthermore includes the following steps: Oxidizing the ablated silicon surface, and etching the ablated and oxidized surface.

In a currently preferred embodiment of the invention, the method relates to the manufacture of platforms in single crystal, platform bodies, especially those comprising silicon.

The removing by means of laser ablation can, according to a further development of the invention, occur especially in layers.

This method has advantages including, for example, that no forming dies must be produced at high cost, or, for example, in the case of grinding with diamond tools, high value material being ground away and, therewith, consumed.

For an optimal surface perfection, it is currently preferred for the laser ablation to use pulse durations in the range, or below the range, of the interaction time of the electron gas with the crystal lattice, wherein the interaction time lies in the pico second range. The pulse durations lie consequently, for example, in the pico second and femtosecond range. In this way, it is assured that, during the laser irradiation, the material does not further melt to cause an increased roughness, but, instead, the energy of the laser pulse is just absorbed by the electron gas. Then, when the irradiation by a laser pulse has already ended, the energy is transferred from the electron gas to the lattice, so that the material is shock vaporized, without additional material being melted. In the case of intensities of more than 10¹⁰ W/cm², materials such as Si and metals are vaporized. Due to the short times, the melting zone and therewith the associated roughness are markedly lessened.

In a further development of the invention, the laser ablation occurs by means of ultrashort laser pulses, especially with laser pulses in the time range of 100 femtoseconds up to some 10 s of pico seconds.

The duration of a laser pulse amounts, for example, to no more than 30 pico seconds, preferably no more than 20 pico seconds, further preferably no more than 15 pico seconds, and especially preferably no more than 10 pico seconds.

The duration of a laser pulse amounts, for example, to not less than 100 femtoseconds, especially not less than 200 femtoseconds

In a further development of the invention, the power of a laser pulse amounts to more than 10¹⁰ watt/cm².

In an embodiment of the invention, the laser can be, for example, a diode pumped, Nd:YVO₄ MOPA laser.

Other details for laser ablation are disclosed, for example, in the paper of A. Gillner et al. “High quality laser machining for tool and part manufacturing using innovative machining systems and laser beam sources” Proc. of the 3rd CIRP Int. Conf. on High Performance Cutting (HPC), Dublin, Ireland, Jun. 12-13, 2008.

In a further development of the invention, the etching occurring after the laser ablation is in the form of HF etching.

In a further development of the invention, the removing of material by means of laser ablation leads to a contour, which extends rotationally symmetrically around an axis perpendicular to the surface of the silicon body.

The platform of the invention comprises a platform body with a membrane bed for supporting a measuring membrane, wherein the membrane bed has a contour, which essentially corresponds to the bend line of the measuring membrane in the case of contact of the center of the membrane bed by the measuring membrane, wherein the contour is obtainable via the method of the invention.

In a further development of the invention, the contour of the membrane bed has a maximum depth Dₘₐₓ of not less than 4 μm, especially not less than 8 μm, further preferably not less than 12 μm and especially preferably not less than 16 μm.

In additional embodiments of the invention, depths Dₘₐₓ of not less than 20 μm, especially not less than 25 μm, are achieved.

For example, at the 19th MicroMechanics Europe Workshop in September 2008, Polster et al. presented AIN membranes, which, in the case of a diameter of, for instance, 1.5 mm and a thickness of, for instance, 0.3 μm, exhibited a pressure-dependent deflection of 25 μm to over 30 μm. A platform of the invention is suitable also for such membranes.

The contour of the membrane bed can be described, for example, by the equation:

D(r)=Dₘₐₓ(1−(r/R)²)²

wherein r is the radial distance of the considered point from the axis of the rotationally symmetric contour, and D(r) describes the depth with respect to a plane defined by the edge of the contour in the case of r=R.

The deflectable diameters of the measuring membranes, which essentially amount to 2*R, have a value of, for example, not less than 0.5 mm, especially not less than 1 mm.

Especially measuring membranes for small pressure ranges in the order of magnitude of no more than 40 mbar and especially no more than 20 mbar can, however also in such case have larger diameters; for example, diameters of between 6 mm and 2 mm.

The platform body can especially be composed of metal, glass, ceramic or a semiconductor material, wherein semiconductor materials, especially Si, are currently preferred.

The pressure sensor of the invention includes a measuring membrane, which is positioned over the membrane bed of the invention and fixedly connected with the platform body.

A pressure difference sensor of the invention includes a measuring membrane which is positioned between two membrane beds and fixedly connected with the two platform bodies.

The pressure sensor of the invention is especially produced with so-called full-wafer bonding technology, wherein a measuring membrane wafer is joined with one platform wafer or two platform wafers, before the sensors are separated into single units.

The invention will now be explained in greater detail based on the examples of embodiments presented in the appended drawing, the figures of which show as follows:

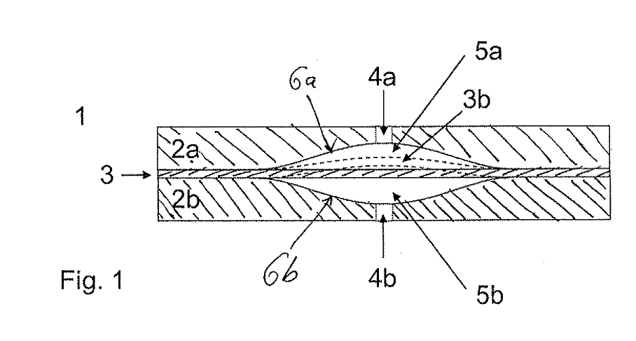

FIG. 1 a schematic longitudinal section through an example of an embodiment of a pressure difference sensor of the invention;

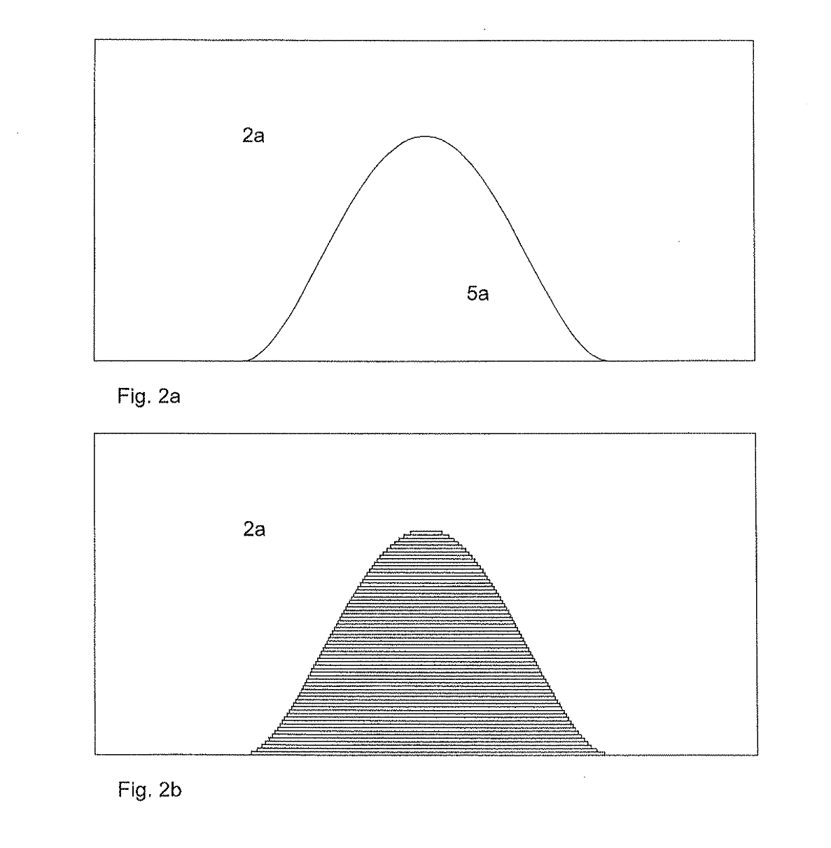

FIG. 2a a longitudinal section through an axially symmetric, aspherical contour, which is to be prepared for the membrane bed of the platform;

FIG. 2b a longitudinal section through the contour of FIG. 2a, which, for preparation, is separated into circularly shaped layers, which are removed from the material of the platform body, wherein the resulting steps at the transitions of the layers are recognizable;

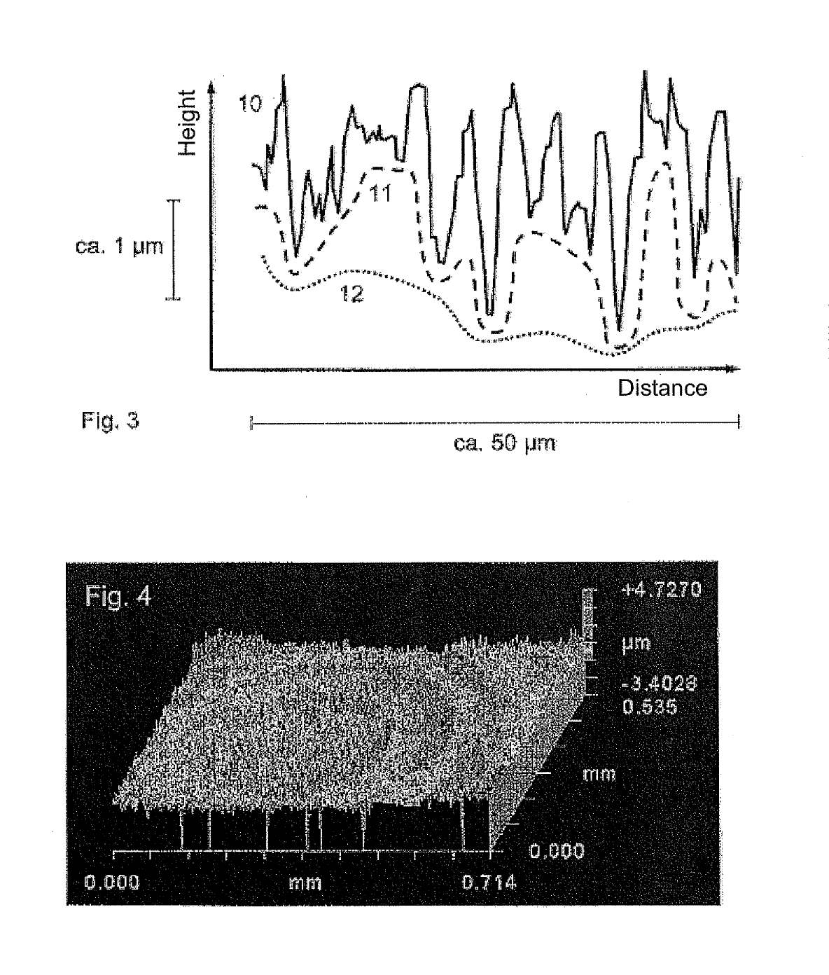

FIG. 3 a schematic representation of the resulting roughness after each of the method steps of laser ablation, oxidation and etching; and

FIG. 4 white light interferometer data of the center of a membrane bed after the laser ablation.

The pressure difference sensor shown in FIG. 1 includes a flexible measuring membrane 3 and two platforms 2a and 2b. In surfaces of platforms 2a and 2b, aspherically formed cavities 5a and 5b have been prepared in such a manner that the surfaces of the cavities can serve as membrane beds 6a, 6b for supporting the measuring membrane 3 in the case of pressure overload from one of the two directions. Extending through the platforms are bores 4a and 4b, via which pressures to be measured are transmitted to the measuring membrane. The pressures can, in such case, directly involve the pressures of the measured medium, or be the pressures of a pressure transfer medium. Presented with the dashed lines is the deflected membrane for the case, in which the pressure in cavity 5b is greater than in cavity 5a.

In the currently preferred method, preparation of the aspherical membrane bed in silicon occurs in three steps.

First, the shape of the membrane bed is prepared by means of laser ablation—thus removing or evaporating material by means of laser light—with ultrashort laser pulses. In this way, it is possible via predetermined geometric surfaces, in this case circular surfaces, to evaporate Si material in layers with layer thicknesses of a few 100 nm, without causing the material to melt.

The radius of the circularly shaped layers is varied in such a manner, that the desired aspherical shape is approximately manufactured—typically with a maximal depth dₘₐₓ of some μm—in the manner presented in FIG. 2b, in order to approximate the contour shown in FIG. 2a.

Due to the removal of the silicon in layers by means of laser ablation, steps are formed at the transitions of one layer to the next. The process of laser removal additionally causes roughness in the order of magnitude below 1 μm, wherein, with each additional layer, i.e. with increasing depth of the membrane bed, the roughness has a tendency to grow cumulatively. The steps at the transitions from one layer depth to the next and the resulting peaks due to the roughness of the laser removal lead to the fact that, in the case of an overload on the membrane bed, the membrane would be exposed locally to higher mechanical stresses, if the membrane bed were to be left in this state. This could, in certain circumstances, degrade the overload resistance of the supported measuring membranes.

Therefore, in a currently preferred embodiment of the invention, the material is smoothed after the laser ablation by means of a chemical treatment.

To this end, the Si material is first of all oxidized, so that principally the projecting peaks and edges of the membrane bed are transformed into SiO₂.

In an additional step, the surface is processed by means of an established etching method, namely HF etching, so that the earlier obtained SiO₂ is removed and the roughness of the surface is significantly reduced.

With the oxidation and the subsequent etching of the oxide, the aspherical membrane bed prepared via laser ablation is thus prepared with trusted methods of semiconductor processing technology with a sufficiently smooth surface, which assures the supporting of the membrane and minimizes local mechanical stresses in the case of overload.

The schematic longitudinal section shown in FIG. 3 through a membrane bed contour with a lateral extent of about 50 μm schematically shows the roughness of the silicon surface after the various preparation steps, wherein the vertical coordinate is presented in a strongly exaggerated manner.

The solid line 10 schematically shows a typical roughness of the silicon surface directly after the laser ablation. The dashed line 11 and the dotted line 12 schematically show the surface, respectively, after the oxidation and after the HF etching. Since principally protruding contour elements of the silicon material are affected by the oxidation, these are what is removed during the subsequent etching step, and so a reduction of the roughness is achieved, whereby the suitability of the contour as a membrane bed for a measuring membrane is increased.

The white light interferometer data illustrated in FIG. 4 come from the center of the surface of a membrane bed after laser ablation has occurred. It can clearly be recognized that the desired shape was circularly hollowed out in layers. The achieved roughness is here still above the order of magnitude of the layer thickness (250 nm), and is yet to be smoothed by means of oxidation and etching.

1-15. (canceled)

16. A method for the manufacture of a platform with a membrane bed, comprising the steps of:
providing a platform body, which comprises silicon; and
removing silicon material from a surface of the platform body by means of laser ablation.

17. The method as claimed in claim 16, further comprising the steps of:
oxidizing the ablated surface; and
etching the ablated and oxidized surface.

18. The method as claimed in claim 16, wherein:
the removing by means of laser ablation occurs in layers.

19. The method as claimed in claim 16, wherein:
the laser ablation occurs by means of ultrashort laser pulses, especially with laser pulses in time range of some 100 femtoseconds up to some 10 s of pico seconds.

20. The method as claimed in claim 19, wherein:
the duration of a laser pulse amounts to no more than 30 pico seconds, preferably no more than 20 pico seconds, further preferably no more than 15 pico seconds, and especially preferably no more than 10 pico seconds.

21. The method as claimed in claim 19, wherein:
the duration of a laser pulse amounts, for example, to not less than 100 femtoseconds, especially not less than 200 femtoseconds

22. The method as claimed in claim 19, wherein:
the power of a laser pulse amounts to more than 10¹⁰ Watt/cm².

23. The method as claimed in claim 16, wherein:
the removing of material by means of laser ablation leads to a contour, which extends rotationally symmetrically around an axis perpendicular to the surface of the platform body.

24. The method as claimed in claim 23, wherein:
the contour is described by the equation:
D(r)=Dₘₐₓ(1−(r/R)²)²,
wherein r is the radial distance of the considered point from the axis, and D(r) describes depth with respect to a plane defined by the edge of the contour in case of r=R.

25. A platform, comprising:
a platform body with a membrane bed, which has a contour for supporting a measuring membrane, wherein the contour essentially corresponds to a bend line of said measuring membrane, wherein:
the contour is obtainable via a method as claimed in claim 16.

26. The platform as claimed in claim 25, wherein:
the contour of the membrane bed is described by the equation:
D(r)=Dₘₐₓ(1−(r/R)²)²
wherein r is the radial distance of the considered point from the axis of the rotationally symmetric contour, and D(r) describes the depth with respect to a plane defined by the edge of the contour in the case of r=R.

27. The platform as claimed in claim 25, wherein:
the contour has a maximum depth Dₘₐₓ with a value of not less than 4 μm, especially not less than 8 μm, preferably not less than 12 μm and especially preferably not less than 16 μm.

28. The platform as claimed in claim 25, wherein:
the platform body comprises a semiconductor material, especially Si.

29. A pressure sensor, comprising:
a measuring membrane and at least one platform as claimed in claim 25, and
a transducer for transducing a pressure dependent deformation of the measuring membrane into an electrical or optical signal, wherein:
the measuring membrane is positioned opposite the membrane bed of the platform and is fixedly connected with the platform body.

30. The pressure sensor as claimed in claim 29, wherein:
the pressure sensor is a pressure difference sensor for registering the difference between a first media pressure and a second media pressure, wherein the pressure sensor includes two platforms, and wherein the measuring membrane is positioned between the two platforms and is fixedly connected with the two platform bodies.
